(19) United States
(12) Patent Application Publication
(10) Pub. No.: US 2010/0272892 A1
(43) Pub. Date: Oct. 28, 2010

(54) FILM FORMATION REACTIVE APPARATUS AND METHOD FOR PRODUCING FILM-FORMED SUBSTRATE

(75) Inventors: Hidenori KOBAYASHI, Omura-shi (JP); Kouichi NISHIKIDO, Omura-shi, Nagasaki (JP); Motonori NAKAMURA, Omura-shi, Nagasaki (JP)

Correspondence Address: GREENBLUM & BERNSTEIN, P.L.C., 1950 ROLAND CLARKE PLACE, RESTON, VA, 20191, US

(73) Assignee: SUMCO TECHXIV CORPORATION, Nagasaki (JP)

(21) Appl. No.: 12/752,383

(22) Filed: Apr. 1, 2010

(30) Foreign Application Priority Data
Apr. 23, 2009 (JP) 2009-105619

(51) Int. Cl. C23C 16/52; C23C 16/00

(52) U.S. Cl. 427/255.5; 118/665

(57) ABSTRACT

A plurality of partial control zones (an LL zone, an LR zone, and an R zone) that can control a gas flow rate independently in a widthwise direction of a gas flow are configured on an upstream side of the gas inlet port 20B. A control device 66 is disposed to control a gas flow rate for respective partial control zones. The control device 66 obtains a deviation between a film growth rate and a predetermined target film growth rate at a variety of locations on a wafer 28 based on the data of a thickness of a film that has been formed on the wafer 28 by a rotating film formation carried out while rotating the wafer 28, and controls the respective gas flow rates of the partial control zones by using the rotation film growth sensitivity data 72 that defines a sensitivity to a change in a film growth rate distribution during the rotating film formation on the wafer 28 in such a manner that a change in the respective gas flow rates of the partial control zones causes the deviation at a variety of the locations to be reduced.

### CROSS-REFERENCE TO PRIOR APPLICATION

This application relates to and claims the benefit of priority from Japanese Patent Application number 2009-105619, filed on Apr. 23, 2009, the entire disclosure of which is incorporated here in by reference.

### BACKGROUND OF THE INVENTION

The present invention relates to a film formation reactive apparatus that produces a film-formed substrate by carrying out a film formation while rotating a substrate and to a method for producing the film-formed substrate.

A film formation reactive apparatus that produces a film-formed substrate by carrying out a film formation while rotating a substrate has been known. Such a film formation reactive apparatus is provided with a configuration for introducing a gas in a bilaterally symmetric manner to a rotation reference line that is parallel to a direction of introducing a gas and that passes through a central axis for rotating a substrate (basically a central axis of a substrate), and carries out a film formation to a substrate by controlling a gas flow to be bilaterally symmetric.

For instance, for such a film formation growth apparatus, a technique related to a shape of a gas supply opening for making a flow rate of a reactant gas to be uniform has been known (see Patent Citation #1).

On the other hand, as a technique for preventing an abnormal film thickness caused by overlapped influences of an uneven flow rate at a specific location on a substrate by a symmetric flow rate distribution of a gas, a technique in which partition plates that divide a flow of a gas are different from each other at right and left from a rotation reference line (see Patent Citation #2) and a technique in which a forming configuration of a gas flow hole is asymmetric to a reference plane (see Patent Citation #3) have been known.

Moreover, a film formation growth apparatus that can independently control a flow rate of a gas for a respective gas flow path has been known (see Patent Citation #4).

Patent Citation #1: Japanese Patent Application Laid-Open Publication No. 2007-35720

Patent Citation #2:Japanese Patent No. 3516654

Patent Citation #3:Japanese Patent Application Laid-Open Publication No. 2003-168650

Patent Citation #4:Japanese Patent Application Laid-Open Publication No. 2007-324286

### SUMMARY OF THE INVENTION

The techniques that are described in the above Patent Citations #1 to #4 are based on the concept that a gas flows in a bilaterally symmetric manner on a substrate in the case in which a bilaterally symmetric gas is made flow in a film formation growth apparatus. Consequently, inventions of every sort and kind have been carried out based on the premise that a gas flow is bilaterally symmetric.

On the other hand, the inventors of the present invention have found the following conditions by observing an influence to a gas flow due to a rotation of a substrate.

FIG. 1 is a view illustrating a gas flow for a film formation reactive apparatus.

A substrate 201 is disposed on a susceptor 202. In the case in which the susceptor 202 is rotated and a gas is supplied from a gas inlet port in a right direction as shown by an arrow in the figure, a pathway course of a gas flow is curved by an influence of a rotation of the substrate 201 and the susceptor 202 as shown in the figure. Consequently, a gas flow is not bilaterally symmetric on the rotation upstream side of a rotation reference line that passes through the center of the substrate 201 and that is parallel to a gas supply direction (a right side in the case in which the substrate 201 is viewed from the gas inlet port) and on the rotation downstream side of the rotation reference line (a left side in the case in which the substrate 201 is viewed from the gas inlet port).

In recent years, a diameter of a substrate is 300 mm or larger in some cases. As a size of a substrate is larger, an influence of a rotation of a substrate to a pathway course of a gas flow is more remarkable.

For a film formation growth apparatus based on the premise that a gas flow is bilaterally symmetric, in the case in which a pathway course of a gas flow is curved as described above, it is difficult to control a thickness of a film on a substrate to be even.

Moreover, for the techniques that are described in the above Patent Citations #2 and #3 for instance, an influence of a curvature of a pathway course of a gas flow due to a rotation is not recognized and not considered. If a technique in which a gas flow is asymmetric due to a configuration of members in a furnace that is described in the Patent Citations #2 and #3 is used, in the case in which the same film-formed substrates are produced by using a plurality of film formation growth apparatuses, a gas flow ratio of right and left is fixed according to a configuration of an apparatus. Consequently, a film thickness of film-formed substrates that are produced by different film formation growth apparatuses can be highly variable disadvantageously.

Compared with this, a plurality of members in a furnace can be prepared, and the members can be selected and used for every film formation growth apparatus to deal with the above problem. However, in that case, it is necessary to prepare a plurality of members in a furnace and it takes a much time for exchanging the members, thereby extremely reducing productivity.

The present invention was made in consideration of the above problems, and an object of the present invention is to provide a technique for improving a film thickness control performance of a substrate in carrying out a film formation while rotating a substrate.

In order to achieve the above described purpose, a film formation reactive apparatus for forming a film on a substrate according to a first aspect of the present invention comprises a reaction chamber configuration part that configures a reaction chamber in which a substrate is placed; a gas inlet port part that configures gas inlet port that extends in a predetermined range in a widthwise direction along a periphery of the substrate placed inside the reaction chamber for introducing a reactant gas flow into the reaction chamber; a plurality of partial control zones that are configured on an upstream side of the gas inlet port and that can control a gas flow rate; and a gas flow rate control part that controls a gas flow rate of the plurality of partial control zones. The gas flow rate control part comprises a first unit that obtains a deviation between a film growth rate and a predetermined target film growth rate at a variety of locations on the substrate based on the data of a thickness of a film that has been formed on the substrate by a rotating film formation carried out while rotating the substrate; and a second unit that controls the respective gas flow rates of the partial control zones to be adjusted by using the rotation film growth sensitivity data that defines a sensitivity to a change in a film growth rate distribution during the rotating film formation on the substrate in such a manner that a change in the respective gas flow rates of the plurality of partial control zones causes the deviation at a variety of the locations to be reduced. According to the above film formation reactive apparatus, the respective gas flow rates of the partial control zones to be adjusted are controlled by using the rotation film growth sensitivity data that defines a sensitivity to a change in a film growth rate distribution during the rotating film formation on the substrate in such a manner that a change in the respective gas flow rates of the plurality of partial control zones causes the deviation at a variety of the locations to be reduced. Consequently, the conditions of a film formation in a rotation can be considered in an appropriate manner to control a flow rate of a gas, whereby a thickness of a film on a substrate can be even in an appropriate manner.

For the above film formation reactive apparatus, different partial control zones can also be configured on the rotation upstream side and on the rotation downstream side of a reference line that is parallel to a direction of a gas flow caused by the gas inlet port and that passes through a rotation central axis of the substrate. According to the above film formation reactive apparatus, a flow rate of a gas can be controlled independently on the rotation upstream side and on the rotation downstream side. Consequently, an influence of a curvature of a gas flow due to a rotation of the substrate can be considered to control a flow rate of a gas.

For the above film formation reactive apparatus, at least two partial control zones of the rotation upstream side and the rotation downstream side can also be configured on the rotation downstream side of the reference line. According to the above film formation reactive apparatus, a flow rate of a gas on the rotation upstream side and the rotation downstream side can be controlled in an appropriate manner on the rotation downstream side of the reference line.

For the above film formation reactive apparatus, one partial control zone is configured on the rotation upstream side of the reference line and two partial control zones of the rotation upstream side and the rotation downstream side can also be configured on the rotation downstream side of the reference line. According to the above film formation reactive apparatus, a flow rate of a gas can be controlled in an appropriate manner for three partial control zones provided with different influences of a rotation.

For the above film formation reactive apparatus, the plurality of partial control zones can also be provided with a first partial control zone that has a high tendency to contribute to a film formation close to the center of the substrate and a second partial control zone that has a high tendency to contribute to a film formation almost close to the intermediate position of a radius of the substrate. According to the above film formation reactive apparatus, a flow rate of a gas can be controlled independently for two partial control zones provided with parts having different higher sensitivities on the substrate during the rotating film formation, whereby a thickness of a film on a substrate can be even in an appropriate manner.

For the above film formation reactive apparatus, the plurality of partial control zones can also be composed of three partial control zones: a first partial control zone that has a high tendency to contribute to a film formation close to the center of the substrate, a second partial control zone that has a high tendency to contribute to a film formation almost close to the intermediate position of a radius of the substrate, and the other partial control zone. According to the above film formation reactive apparatus, a flow rate of a gas can be controlled for three partial control zones, whereby a configuration related to a control can be simplified.

For the above film formation reactive apparatus, the plurality of partial control zones can also be provided with a third partial control zone that has a high tendency to contribute to a film formation close to the outer circumference of the substrate. According to the above film formation reactive apparatus, a thickness of a film around the outer circumference of the substrate can also be controlled in an appropriate manner.

For the above film formation reactive apparatus, the plurality of partial control zones can also be composed of four partial control zones: the first partial control zone, the second partial control zone, the third partial control zone, and the other partial control zone. According to the above film formation reactive apparatus, a flow rate of a gas can be controlled for four partial control zones, whereby a configuration related to a control can be simplified.

For the above film formation reactive apparatus, a gas adjustment mechanism that adjusts a gas flow rate in the partial control zone can also be disposed for every partial control zone. According to the above film formation reactive apparatus, the number of gas adjustment mechanisms to be disposed is equivalent to that of the partial control zones.

In order to achieve the above described purpose, a method for producing a film-formed substrate while rotating the substrate according to a second aspect of the present invention comprises a step of making a reactant gas to flow to the substrate for a film formation; a step of producing a film-formed substrate by adjusting a gas flow rate for the reactant gas flow to be a predetermined rate for each of a plurality of partial control zones to carry out a film formation while rotating the substrate; a step of obtaining a deviation between a film growth rate and a predetermined target film growth rate at a variety of locations on the substrate based on the data of a thickness of a film that has been formed on the substrate by the rotating film formation carried out while rotating the substrate; a step of determining a gas flow rate adjusted for the respective partial control zones to be adjusted by using the rotation film growth sensitivity data that defines a sensitivity to a change in a film growth rate distribution during the rotating film formation on the substrate in such a manner that a change in the respective gas flow rates of the plurality of partial control zones causes the deviation at a variety of the locations to be reduced; and a step of producing the film-formed substrate by adjusting the respective gas flow rates of the plurality of partial control zones to be the determined gas flow rate to carry out a film formation while rotating a new substrate. According to the above method for producing a film-formed substrate, the respective gas flow rates of the partial control zones to be adjusted are controlled by using the rotation film growth sensitivity data that defines a sensitivity to a change in a film growth rate distribution during the rotating film formation on the substrate in such a manner that a change in the respective gas flow rates of the plurality of partial control zones causes the deviation at a variety of the locations to be reduced. Consequently, the conditions of a film formation in a rotation can be considered in an appropriate manner to control a flow rate of a gas, whereby a thickness of a film on a substrate can be even in an appropriate manner.

### BRIEF DESCRIPTION OF THE DRAWINGS

FIG. 1 is a view illustrating a gas flow for a film formation reactive apparatus.

FIG. 2 is a cross sectional view showing the main components of a film formation reactive apparatus according to an embodiment of the present invention.

FIG. 3 is a view showing a configuration of a part for a gas flow supply of a film formation reactive apparatus according to an embodiment of the present invention.

FIG. 4 is a view showing a configuration of a gas piping system related to a supply control of a gas according to an embodiment of the present invention.

FIG. 5 is a flow chart illustrating an adjustment process of gas flow rate according to an embodiment of the present invention.

FIG. 6 is a view illustrating a film growth rate deviation according to an embodiment of the present invention.

FIG. 7 is a view showing an example of film growth sensitivity data in a rotation according to an embodiment of the present invention.

FIG. 8 is a view showing a configuration of a part for a gas flow supply to test a film formation characteristic for a film formation reactive apparatus.

FIG. 9 is a view illustrating a film formation characteristic for a film formation reactive apparatus.

FIG. 10 is a view showing a configuration of a part for a gas flow supply of a film formation reactive apparatus according to a first modified example of the present invention.

FIG. 11 is a view showing a configuration of a part for a gas flow supply of a film formation reactive apparatus according to a second modified example of the present invention.

FIG. 12 is a view showing a configuration of a part for a gas flow supply of a film formation reactive apparatus according to a third modified example of the present invention.

FIG. 13 is a view showing a configuration of a part for a gas flow supply of a film formation reactive apparatus according to a fourth modified example of the present invention.

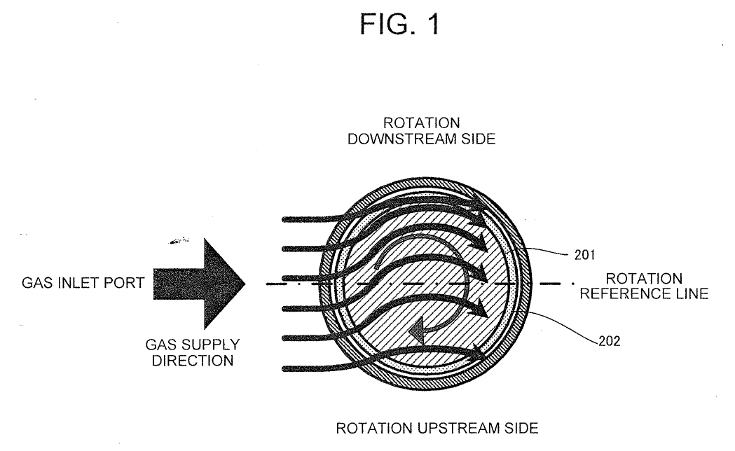

### DESCRIPTION OF THE PREFERRED EMBODIMENTS

A mode for the present invention will be described below in detail with reference to the drawings. The preferred embodiments that will be described in the following do not limit the present invention according to the claims, and all of the elements and combinations thereof that will be described in the embodiments are not essential for solution means of the present invention.

A film formation reactive apparatus according to an embodiment of the present invention will be described in detail in the following.

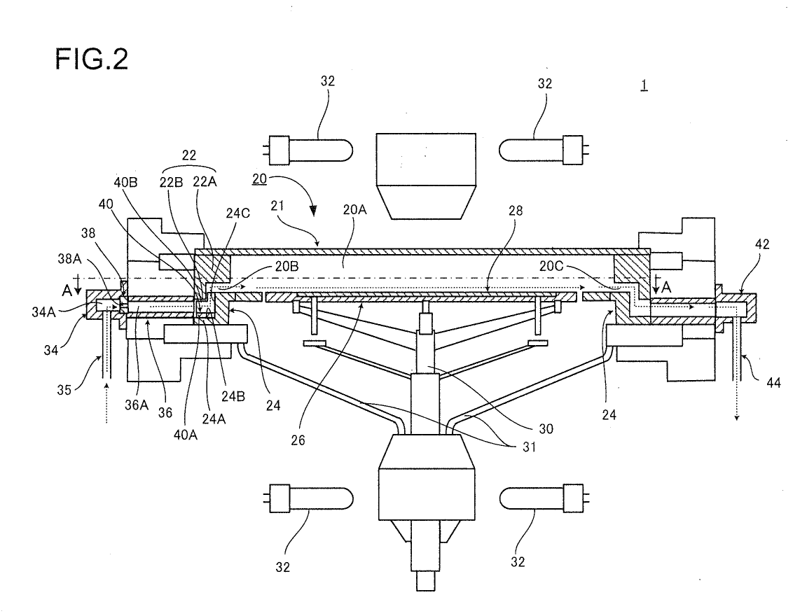

FIG. 2 is a cross sectional view showing the main components of a film formation reactive apparatus according to an embodiment of the present invention. This film formation reactive apparatus can be used to form an epitaxial film of a semiconductor material such as silicon on the surface of a semiconductor wafer such as a silicon wafer.

As shown in FIG. 2, a film formation reactive apparatus 1 is provided with a reaction device 20 having a reaction chamber 20A inside. The shape of the reaction chamber 20A is substantially flat cylindrical. The entire top surface of the reaction chamber 20A is covered by a substantially disc-shaped upper dome 21. In other words, the upper dome 21 forms the ceiling wall of the reaction chamber 20A. The bottom wall of the reaction device 20 is composed of a substantially circular lower liner 24 and a disc-shaped susceptor 26 that is disposed within a circular opening on the inside of the lower liner 24.

An upper liner 22 is provided with a protruding annular part 22A that is downwardly projecting along the entire periphery of the upper liner 22. The protruding annular part 22A of the upper liner 22 is coupled to a periphery 24A of the lower liner 24 to form the side walls of the reaction chamber 20A. A wafer (substrate) 28 is placed on the susceptor 26. The susceptor 26 is coupled to a susceptor support shaft 30 at the bottom surface of the susceptor and is rotatably driven about the center of the wafer 28 as the axis of rotation during the film formation process. A diameter of the wafer 28 is 300 mm for instance.

A plurality of heating lamps 32, 32, . . . for heating are arrayed in circles both above and below the reaction chamber 20A. To enable a radiant heat from the heating lamps 32, 32, . . . to be transmitted optimally to the susceptor 26 and the wafer 28, the main components of the upper dome 21 and the lower dome 31 are made of a heat resistant material having an optically transparent property such as quartz.

The basic structure of the film formation reactive apparatus 1 described above is well known, and therefore a detailed description thereof is omitted from this specification. What follows is a detailed description of a structure for supplying a gas flow to the interior of the reaction chamber 20A of the film formation reactive apparatus 1.

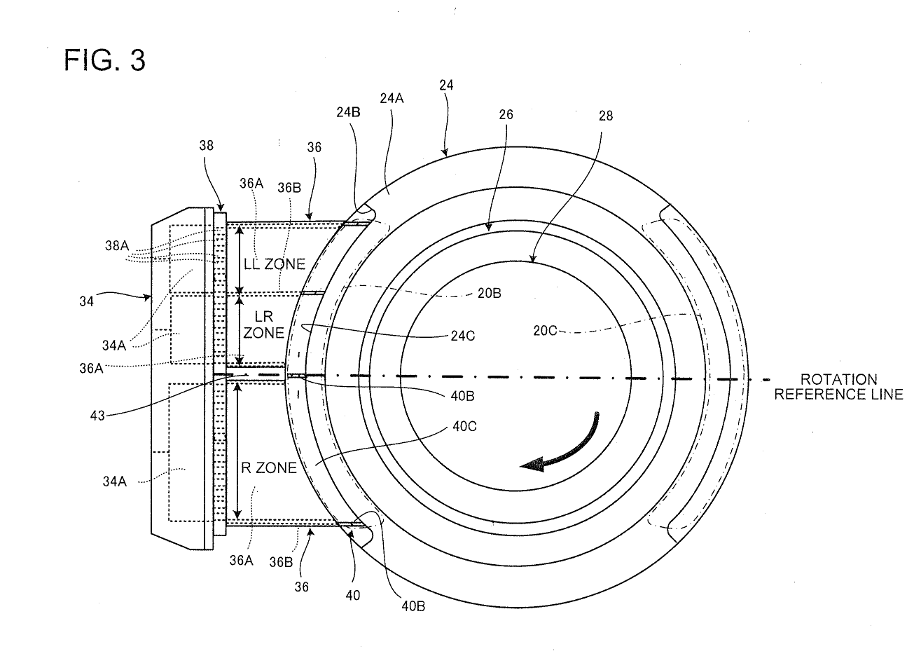

FIG. 3 is a plan view of the lower liner 24 and the susceptor 26, together with a variety of components for gas flow supply mounted on the lower liner 24, as seen along a line A-A shown in FIG. 2. A description of the structure for a gas flow supply of the film formation reactive apparatus 1 will be given in the following with reference to FIG. 2 and FIG. 3.

A gas inlet port 20B is formed at the edge of one side (the left side in the drawings) of the reaction chamber 20A. A gas exhaust port 20C is formed at the edge of a side opposite the gas inlet port 20B of the reaction chamber 20A. As shown in FIG. 2, both the gas inlet port 20B and the gas exhaust port 20C are located at positions near the outside of the periphery of the wafer 28, extending in an arc substantially parallel to the periphery of the wafer 28. The direction in which the gas inlet port 20B and the gas exhaust port 20C extend along the periphery of the wafer 28 (the vertical direction in FIG. 3) is hereinafter referred to as the “widthwise direction”. The dimensions of the widthwise direction of the gas inlet port 20B and the gas exhaust port 20C, that is, the widths, are slightly larger than the diameter of the wafer 28 on the susceptor 26. The centers of the widthwise directions of the gas inlet port 20B and the gas exhaust port 20C, respectively, match the center of the wafer 28 in the same widthwise direction. Therefore, in the interior of the reaction chamber 20A, the reactant gas flows from the gas inlet port 20B to the gas exhaust port 20C in the form of a belt having a width wide enough to cover the entire surface area of the wafer 28. Here, a line that passes through the center of a rotation of the wafer 28 in a direction of a reactant gas flow from the gas inlet port 20B is referred to as a rotation reference line. This belt-shaped reactant gas flow passes over the entire surface area of the wafer 28 and forms an epitaxial film on the surface of the wafer 28. The flow velocity distribution in the widthwise direction of this reactant gas flow determines the film thickness distribution of the epitaxial film on the surface of the wafer 28.

A more detailed description is now given of the structure that configures the gas inlet port 20B described above (a gas inlet port part). Specifically, a step-shaped concave portion 24B is formed on a peripheral portion 24A of the lower liner 24. This step-shaped concave portion 24B is downwardly concave to a greater extent than the other portions of the lower liner 24 as seen in cross-section along the direction of gas flow shown in FIG. 2 (hereinafter this cross-section is referred to as the “vertical cross-section”), and extends in an arc over a wider distance range than the diameter of the wafer in the widthwise direction as shown in FIG. 3. Moreover, a stepped-shaped convex portion 22B is formed on the protruding annular part 22A of the upper liner 22 opposite the above-described step-shaped concave portion 24B. This step-shaped convex portion 22B protrudes downward toward the step-shaped concave portion 24B as seen in the vertical sectional view shown in FIG. 2, and moreover, in the widthwise direction extends in an arc over the same distance range as that of the step-shaped concave portion 24B. The gas inlet port 20B described above is formed between a portion where the step-shaped concave portion 24B of the peripheral portion 24A of the lower liner 24 exists and a portion where the step-shaped convex portion 22B of the protruding annular part 22A of the upper liner 22 exists. The gas inlet port 20B is bent in the shape of a staircase when seen in the vertical sectional view shown in FIG. 2, through which the reactant gas flows in the direction of the dotted line arrows shown in FIG. 2. As a result, the reactant gas flow hits a front wall 24C of the step-shaped concave portion 24B inside the gas inlet port 20B and rises upward to enter the interior of the reaction chamber 20A.

The structure of the gas exhaust port 20C is substantially the same as that of the gas inlet port 20B described above.

An inlet flange 34 for introducing the reactant gas into the interior of the reaction chamber 20A is mounted on an outside surface of the side on which the gas inlet port 20B of the reaction device 20 is located and opposite thereto. Inside the inlet flange 34 are a plurality (for example three) of gas chambers 34A. A plurality (for example three) of gas supply pipes 35 are connected to the inlet flange 34, with the gas supply pipes 35 communicating with the gas chambers 34A.

Between the inlet flange 34 and the gas inlet port 20B are inserted two symmetrically shaped, plane-shaped inserters 36 as shown in FIG. 3. The boundary between the two inserters 36 is located at the center in the widthwise direction of the gas inlet port 20B (on the rotation reference line). Inside the inserters 36 is at least one gas flow path 36A (partial control zones), making, for example, a total of three gas flow paths 36A inside the two inserters 36. In the present embodiment, one gas flow path 36A (an R zone) is formed in the inserter 36 on the right side (the rotation upstream side) of a reference line toward the wafer 28, and two gas flow paths 36A (an LR zone and an LL zone) are formed in the inserter 36 on the left side (the rotation downstream side) of a reference line toward the wafer 28. A width of the LR zone is almost equivalent to that of the LL zone in the present embodiment. The combined width of the two inserters 36 is substantially the same as the width of the gas inlet port 20B. A laterally long, thin, plate-shaped baffle 38 is inserted between the two inserters 36 and the inlet flange 34. Inside the baffle 38 is a plurality of flow rectifying holes 38A (for example 24). The gas chambers 34A inside the inlet flange 34 communicate with a plurality of flow rectifying holes 38A inside the baffle 38, the flow rectifying holes 38A inside the baffle 38 communicate with any of the gas flow paths 36A inside the two inserters 36, and the plurality of gas flow paths 36A inside the two inserters 36 all communicate with the gas inlet port 20B.

An outlet flange 42 for expelling the reactant gas to the exterior of the reaction chamber 20A is mounted on an outside surface of the side on which the gas exhaust port 20C of the reaction chamber 20A is located and opposite thereto. One or a plurality of gas exhaust pipes 44 are connected to the outlet flange 42.

As indicated by the dotted line arrows in FIG. 2, the reactant gas enters the gas chambers 34A inside the inlet flange 34 from the gas supply pipes 35, enters the gas inlet port 20B through the flow rectifying holes 38A inside the baffle 38 and the gas flow paths 36A inside the two inserters 36, passes through the gas inlet port 20B, forms a belt-shaped gas flow, and flows into the interior of the reaction chamber 20A. The belt-shaped gas flow flowing into the interior of the reaction chamber 20A from the gas inlet port 20B passes over the entire surface area of the wafer 28 on the susceptor 26 and forms an epitaxial film on the surface of the wafer 28. Thereafter, the reactant gas flow enters the gas exhaust port 20C, passes through the interior of the outlet flange 42 and exits through the gas exhaust pipe 44. The film thickness distribution of the epitaxial film on the surface of the wafer 28 is determined by the gas flow velocity distribution in the widthwise direction of the reactant gas flow inside the reaction chamber 20A. The gas flow velocity distribution inside the reaction chamber 20A is determined by the gas flow velocity distribution of the plurality of gas flow paths 36A inside the two inserters 36.

A more detailed description is now given particularly of the structure of the inserters 36, the baffle 38, the inlet flange 34, and the gas inlet port 20B.

Inside the inserters 36, the plurality of gas flow paths 36A that communicate from the baffle 38 side to the gas inlet port 20B side is arrayed in line in the widthwise direction. Adjacent gas flow paths 36A are separated from each other by side walls 36B. The shape of the gas flow paths 36A in cross-section as cut across the flow of gas at a right angle thereto (hereinafter, this cross-section in a direction that is at a right angle to the flow of gas is referred to as the “lateral cross-section”) is for example rectangular, circle, or a shape closely approximate thereto. In the present embodiment, the number of gas flow paths 36A inside two inserters 36 is for example three.

Inside the baffle 38 a plurality of flow rectifying holes 38A (for example 24) communicating from the inlet flange 34 side to the inserter 36 side is arrayed in a single line in the widthwise direction. The plurality of flow rectifying holes 38A communicates with the gas flow paths 36A in the inserters 36. In the present embodiment, the plurality of flow rectifying holes 38A communicates with one gas flow path 36A. The shape of the flow rectifying holes 38A is lateral cross-section of a long, narrow slit in the widthwise direction. The flow rectifying holes 38A fulfill the function of flattening the distribution of the gas flow velocity inside the gas flow paths 36A.

As shown in FIG. 2 and FIG. 3, a plurality of separate gas chambers 34A (for example three) is formed inside the inlet flange 34. Each of these multiple gas chambers 34A inside the inlet flange 34 communicates with some of the plurality of flow rectifying holes 38A inside the baffle 38. A plurality of gas supply pipes 35 (for example three) is connected to the plurality of gas chambers 34A in the inlet flange 34.

As shown in FIG. 2 and FIG. 3, a blade unit 40 is inserted into the step-shaped concave portion 24B that occupies approximately half the area upstream of the gas inlet port 20B.

The blade unit 40 comprises a flat, planar base plate 40A in the same arc shape as that of the step-shaped concave portion 24B and a plurality of blades 40B (for example four) projecting perpendicularly from the top of the base plate 40A. The blade unit 40 is an independent and separate component not integrated into a single unit with the lower liner 24 (in other words, is detachable from the lower liner 24), and is placed on the top of the step-shaped concave portion 24B of the lower liner 24. Each of the multiple blades 40B of the blade unit 40 is aligned with one of the side walls 36B of the gas flow paths 36A inside the inserters 36. Accordingly, a plurality of separate and individual gas transport channels 40C (for example three) is formed on the step-shaped concave portion 24B by the plurality of blades 40B. Each of these multiple gas transport channels 40C communicates with one of the multiple gas flow paths 36A inside the two inserters 36.

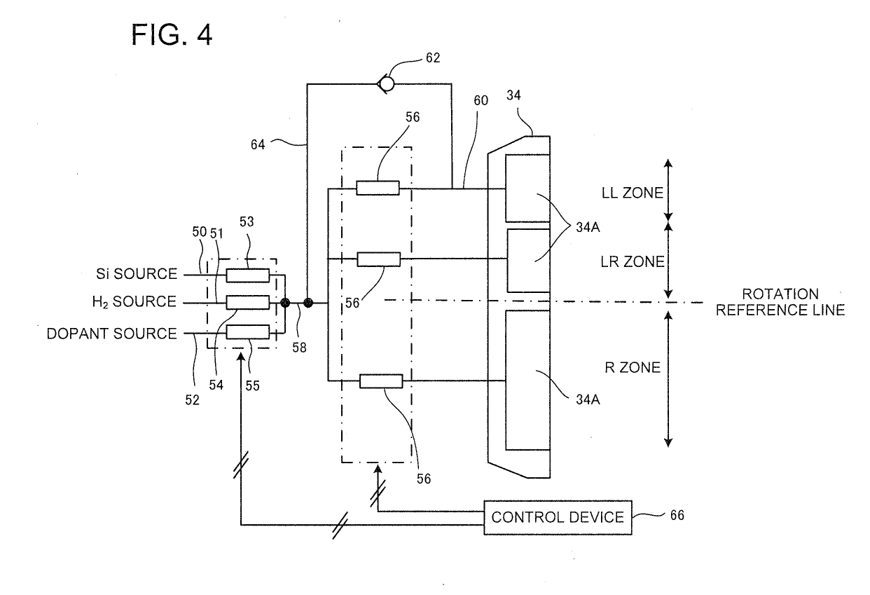

FIG. 4 is a piping diagram showing the configuration of a gas piping system provided on the outside of the reaction device 20 described above for supplying the reactant gas to the reaction device 20.

The reactant gas is a mixed gas consisting of multiple component gases, such as silicon gas, hydrogen gas and a predetermined dopant gas. As a result, as shown in FIG. 4, there is a plurality of gas sources, such as a silicon gas source, a hydrogen gas source, and a dopant gas source, with a plurality of component gas supply pipes 50, 51, 52 coming from the respective plurality of component gas sources converging at a single reactant gas supply source pipe 58. Gas flow rate regulators 53, 54, 55 are provided on each of the component gas supply pipes 50, 51, 52. The gas flow rate regulators 53, 54, 55 are controlled by a control device 66 using a computer, enabling the overall flow rate of the reactant gas supplied to the reaction device 20 and the relative proportions of the component gases in the reactant gas to be adjusted.

The reactant gas supply source pipe 58 branches into a plurality of (for example three) reactant gas supply branch pipes 60. Each of the plurality of reactant gas supply branch pipes 60 is connected to one of a plurality of (for example three) gas chambers 34A, 34A, . . . inside the inlet flange 34.

In the present embodiment, one gas flow rate regulator (a gas adjustment mechanism) 56 capable of adjusting the gas flow rate essentially steplessly (that is, continuously) is provided for one reactant gas supply branch pipe 60 that communicates with one gas flow path 36A (one gas chamber 34A) on the rotation upstream side of a rotation reference line (a right side toward the wafer 28 (a lower side in FIG. 4)). Moreover, one gas flow rate regulator 56 is provided for one reactant gas supply branch pipe 60 that communicates with one gas flow path 36A (one gas chamber 34A) on the rotation upstream side in two gas flow paths 36A (gas chambers 34A) on the rotation downstream side of a rotation reference line (a left side toward the wafer 28 (an upper side in FIG. 4)). Moreover, one gas flow rate regulator 56 is provided for one reactant gas supply branch pipe 60 that communicates with one gas flow path 36A on the rotation downstream side of a rotation reference line. The above three gas flow rate regulators 56 are controlled by the control device 66, enabling the gas flow rate (a gas capacity flowing per unit time) flowing to each of the gas flow path 36A of the three areas of an area on the rotation upstream side of the gas inlet port 20B (the R zone: the partial control zone), the gas flow path 36A of an area on the rotation upstream side in the rotation downstream side (the LR zone: the partial control zone), and the gas flow path 36A of an area on the rotation downstream side in the rotation downstream side (the LL zone: the partial control zone) to be adjusted to any value separately and independently of all the others. Consequently, an area on the rotation upstream side and an area on the rotation downstream side have different flow rates for instance.

Further, in the case in which the gas pressure in the reactant gas supply source pipe 58 becomes abnormally high due to a malfunction in one of the gas flow rate regulators 56 or for some other reason, a safety relief pipe 64 having a safety relief valve 62 for releasing excess gas to the outside of the reaction chamber 20A and lowering the pressure is connected between the reactant gas supply source pipe 58 and a single reactant gas supply branch pipe 60 that is connected to the single outermost gas flow path 36A of the three gas flow paths 36A.

In the gas piping system shown in FIG. 4 described above, a gas flow rate regulator 56 is provided corresponding to each of the partial control zones of the R zone, the LR zone, and the LL zone in such a manner that the gas flow rates of each of the partial control zones can be adjusted independently from each other.

A description is now given of the operation of the film formation reactive apparatus having the configuration described above.

The flow velocity distribution in the widthwise direction of the reactant gas flow into the reaction chamber 20A from the gas inlet port 20B is controlled by each of the gas flow velocities of the three gas flow paths 36A arrayed across the entire gas inlet port 20B in the widthwise direction thereof.

The flow rectifying holes 38A in the baffle 38 located upstream of the gas flow paths 36A have the effect of equalizing the flow rate distribution within the gas flow paths 36A, by which the requirement relating to flow velocity described above is even more easily and better satisfied. Specifically, the flow rectifying holes 38A are long, narrow slit-shaped holes extending in the widthwise direction of the gas flow paths 36A, having a height that is constant across the width of the gas flow paths 36A. As the gas flow passes through such narrow flow rectifying holes 38A, the gas flow velocity distribution in the widthwise direction of the gas flow immediately after exiting the flow rectifying holes 38A is constant over the width of the gas flow paths 36A, and further, that gas flow velocity distribution determines the gas flow velocity distribution of the gas flow when the gas flow later flows through the gas flow paths 36A.

Further, as described with reference to FIG. 2 and FIG. 3, the gas flow velocity distribution formed by the plurality of gas flow paths 36A inside the inserters 36 is well maintained inside the step-shaped concave portion 24B by the plurality of gas transport channels 40C formed by the blade unit 40 placed atop the step-shaped concave portion 24B in the front half of the gas inlet port 20B. Then, when the gas flow passes the step-shaped concave portion 24B, the gas flow strikes the front wall 24C of the step-shaped concave portion 24B and rises upward before flowing into the interior of the reaction chamber 20A, and further, the gas inlet port 20B portion downstream from the front wall 24C is continuous in the widthwise direction without being divided. As a result, fluctuations in the gas flow velocity distribution due to the blade unit 40B are diminished by the rear half of the gas inlet port 20B which is not divided, thus improving the smoothness of flow velocity distribution in the widthwise direction of the gas flow entering the reaction chamber 20A from the gas inlet port 20B.

As a result of the combined effects of the parts described above, it becomes possible to adjust the gas flow velocity distribution in the widthwise direction of the gas flow inside the reaction chamber 20A to a desired distribution.

In the next place, a detailed description is given of a gas flow rate adjustment control performed by the control device 66 shown in FIG. 4.

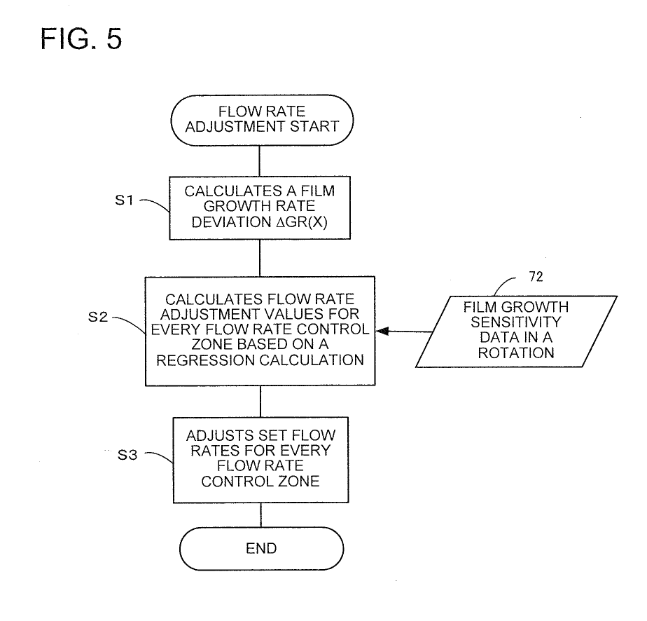

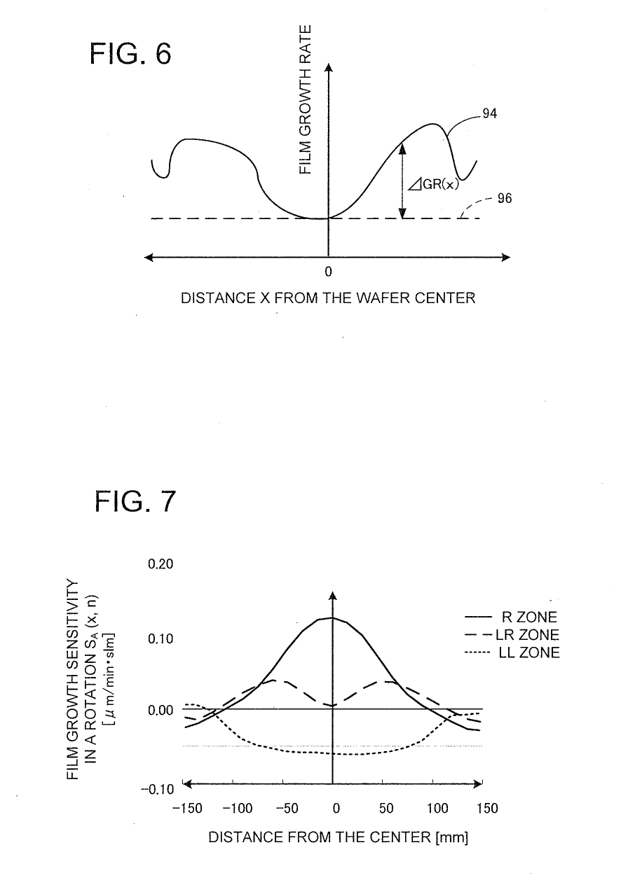

FIG. 5 is a flow chart illustrating an adjustment process of gas flow rate according to an embodiment of the present invention. FIG. 6 is a view illustrating a film growth rate deviation according to an embodiment of the present invention. FIG. 7 is a view showing an example of film growth sensitivity data in a rotation according to an embodiment of the present invention.

Before the gas flow rate adjustment processing is carried out, an experimental film formation is carried out on the wafer 28 and a measurement processing of the wafer that has been obtained by the experimental film formation is carried out. More specifically, as with the film formation on the wafer 28 to create a product, this film formation is also carried out with the wafer 28 rotating (the experimental film formation). After the experimental film formation, the thickness of the formed film is measured at multiple different places on the surface of the wafer 28 (a measurement processing). In the experimental film formation conducted, the control device 66 adjusts the above described gas flow rate distribution (that is, the gas flow rates of the plurality of gas flow rate regulators 56) to a preset initial flow rate setting. Any appropriate flow rate value assumed to be appropriate based on experience, for example, may be employed as the initial flow rate setting.

In the gas flow rate adjustment process, as shown in FIG. 6, based on film thickness data obtained by measurement in the experimental film formation for the wafer 28, the film growth rate deviation ΔGR(x) is calculated as a function of the distance x from the center of the wafer 28 by the control device 66 (step S1). For example, based on the film thickness data and the time needed for film growth, a film growth rate of 94 (μm/min) as shown in FIG. 6 is calculated as a function of distance x from the center of the wafer. Then, a difference between that film growth rate 94 and a predetermined target film growth rate 96 (for example, a minimum rate, a maximum rate or an average rate of the film growth rate 94, or an arbitrary rate value set in advance) is obtained as the film growth rate deviation ΔGR(x) by the control device 66. In the present embodiment, the film growth rate deviation ΔGR(x) is calculated at each of multiple predetermined different distances x set in advance as sampling points.

Thereafter, flow rate adjustment values for each flow rate regulator 56 are calculated based on the film growth rate deviation ΔGR(x) at the multiple sampling points calculated by the control device 66 (step S2). In this calculation, film growth sensitivity data in a rotation set in advance in the control device 66 is referenced. The film growth sensitivity data, as shown in the example shown in FIG. 7, is the aggregate of film growth sensitivity functions in a rotation S₁ (x, n) to S_{N} (x, n) set in advance for each flow rate regulator 56 (put another way, for each partial control zone) where N is the number of partial control zones; although N=3 in the example shown in the drawing, such is but one example thereof. In FIG. 7, n=1.5.

The film growth sensitivity function in a rotation S_{A} (x, n) related to a partial control zone A is indicated as shown in the following. That is, S_{A} (x, n)={GR_{A} (x, n)−GR_{A} (x, 1)}/L. In this expression, x represents a distance (mm) from the center of a wafer at a location X on a straight line in the widthwise direction of a gas flow that passes through the center of the wafer, GR_{A} (x, n) represents a film growth rate (μm/min) at a location X on the wafer in the case in which a film formation is carried out while the wafer is rotated under the conditions that a gas flow rate that flows in the reaction chamber is L (slm), an aperture of a valve other than the partial control zone A is constant, and an aperture of a valve for the partial control zone A is n folds of that of others.

The film growth sensitivity function in a rotation S_{A} (x, n) expresses a ratio of change (μm/min·slm) in the film growth rate (μm/min) on the wafer 28 to change in a gas flow rate (slm) of a gas that flows through the corresponding partial control zone in the case in which a film formation is carried out while the wafer is rotated as a function of the distance x from the center of the wafer.

For instance, a first film growth sensitivity function in a rotation S₁ (x, n) is corresponded to a partial control zone (a lower gas flow path 36A shown in FIG. 3: R zone) that is located on the most rotation upstream side, the second film growth sensitivity function in a rotation S₂ (x, n) is corresponded to a partial control zone (LR zone) that is located on the next most rotation upstream side, with the film growth sensitivity function in a rotation Sᵢ (x, n) corresponding to a partial control zone that is located on a successively more rotation downstream side as the suffix number represented by i increases up to the final Nth (in the present example the third) film growth sensitivity function in a rotation S_{N} (x, n) (in the present example S₃ (x, n)) corresponding to a partial control zone that is located on a most rotation downstream side.

For example, as shown in FIG. 7, examining the film growth sensitivity function in a rotation S₁ (x, 1.5) corresponding to a partial control zone (an R zone) that is located on a most rotation upstream side, it can be seen that the change in a gas flow rate in the partial control zone has a greater effect on the film growth rates at an area (a center part) that is closer to the center of the wafer. In addition, for example, examining the film growth sensitivity function in a rotation S₂ (x, 1.5) corresponding to a partial control zone (an LR zone) that is located on a rotation upstream side on the rotation downstream side, it can be seen that the change in a gas flow rate in the partial control zone has a greater effect on the film growth rates at an area (a middle part) that is closer to the almost intermediate position of a radius of the wafer. In addition, for example, examining the film growth sensitivity function in a rotation S₃ (x, 1.5) corresponding to a partial control zone (an LL zone) that is located on a rotation downstream side on the rotation downstream side, it can be seen that the change in a gas flow rate in the partial control zone has a greater effect on the film growth rates at an area (an edge part) that is closer to the periphery of the wafer.

Returning to the descriptions of FIG. 5, a recurrent calculation described below is carried out using the control device 66 based on the film growth rate deviation ΔGR(x) as shown in FIG. 6 and the film growth sensitivity functions in a rotation S₁(x) to S₃(x) for each gas flow rate regulator 56 (each partial control zone) as shown in FIG. 7, and flow rate adjustment values aₗ to a_{N} for each flow rate regulator 56 (each partial control zone) are calculated.

In other words, for the film growth rate deviation ΔGR(x) at each sampling point xⱼ, the following equation holds true:

ΔGR(xⱼ)=a₁S₁(xⱼ)+a₂S₂(xⱼ)+a₃S₃(xᵢ)+ . . . +a_{N}S_{N} (xⱼ)

Where there are M sampling points xⱼ (where M>N), the above-described equation holds true for M points of j=1 to M. Well-known recurrent calculations are executed using these equations for M, as a result of which flow rate adjustment values a₁ to a_{N} for each flow rate regulator 56 (each partial control zone) that best satisfy the equations for M simultaneously are obtained. In the case in which any of the partial control zones is not to be adjusted and a gas flow rate is constant, since a flow rate adjustment value is 0, the term of the film growth sensitivity function in a rotation corresponding to a partial control zone in which a gas flow rate is constant can be removed from the above equation. In other words, the term of the film growth sensitivity function in a rotation corresponding to a partial control zone in which a gas flow rate is constant can be removed in the above equation.

Once the flow rate adjustment values a₁ to a_{N} for each flow rate regulator 56 (partial control zone) are obtained as described above, the current flow rate settings for the flow rate regulators 56 (partial control zone) are adjusted using the flow rate adjustment values a₁ to a_{N} described above (step S3). A wafer can also be rotated to carry out a film formation by using the flow rate settings that have been adjusted in the step S3, a thickness of a film of a wafer that has been obtained in the film formation can be measured, and the processes from the step S1 are repeated to adjust the flow rate settings.

A wafer is rotated to carry out a film formation by using the flow rate settings that have been adjusted as described above, and a wafer that is a product (a film-formed substrate) is produced. Using the flow rate settings that have been adjusted as described above, the uneven film growth rate 94 shown in FIG. 6 is rectified and a uniform film growth rate that is closer to the target film growth rate 96 is obtained. As a result, a uniformity of a thickness of a film of a wafer can be improved.

In the next place, a film formation characteristic for a film formation reactive apparatus will be described prior to the description of the modified examples according to the present invention.

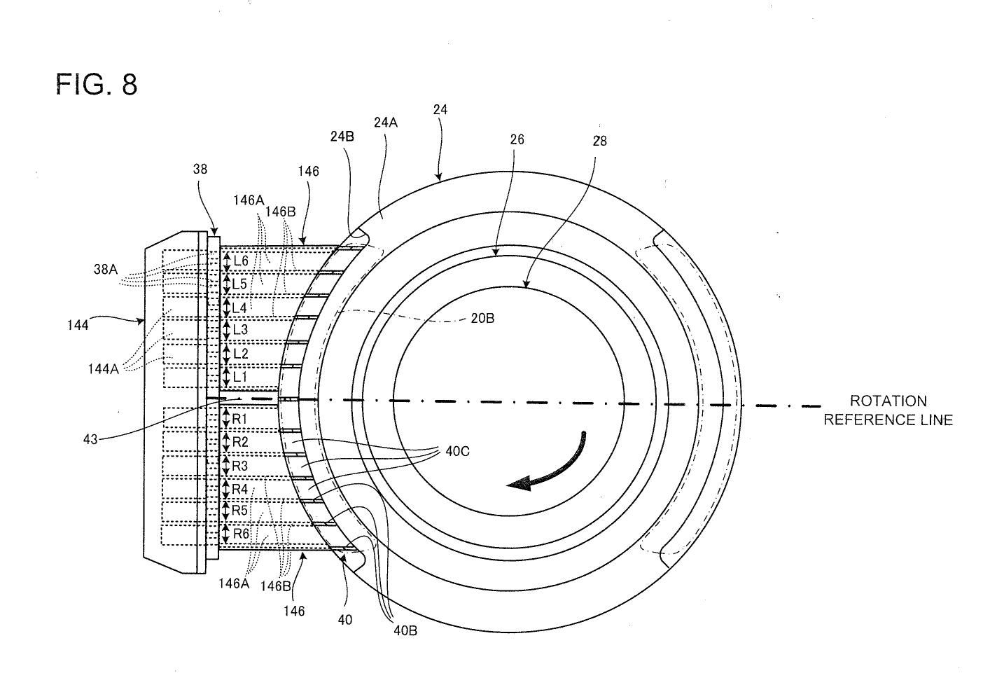

FIG. 8 is a view showing a configuration of a part for a gas flow supply to test a film formation characteristic for a film formation reactive apparatus. Here, elements equivalent to those illustrated in FIG. 2 are numerically numbered similarly.

For the film formation reactive apparatus 1 in order to test the film formation characteristics, the film formation reactive apparatus that is provided with an inserter 146 in place of an inserter 36 and that is provided with an inlet flange 144 in place of an inlet flange 34 was prepared.

A plurality of (for instance six) gas flow paths 146A are formed in each of the inserters 146. R1 and R2 to R6 are disposed from the part closer to a reference line for the gas flow path 146A of the inserter 146 on the right side, and L1 and L2 to L6 are disposed from the part closer to a reference line for the gas flow path 146A of the inserter 146 on the left side. For the gas flow paths R1 and L1, a distance from the center line (a reference line) of a wafer is in the range of 5.3 mm to 32.9 mm. For the gas flow paths R2 and L2, a distance from the center line (a reference line) of a wafer is in the range of 34.9 mm to 62.2 mm. For the gas flow paths R3 and L3, a distance from the center line (a reference line) of a wafer is in the range of 64.1 mm to 91.3 mm. For the gas flow paths R4 and L4, a distance from the center line (a reference line) of a wafer is in the range of 93.3 mm to 120.5 mm. For the gas flow paths R5 and L5, a distance from the center line (a reference line) of a wafer is in the range of 122.5 mm to 149.7 mm. For the gas flow paths R6 and L6, a distance from the center line (a reference line) of a wafer is in the range of 151.7 mm to 178.9 mm.

The inlet flange 144 is provided with a gas chamber 144A that communicates with a flow rectifying holes 38A inside the baffle 38 at a position that is corresponded to the gas flow path 146A. A gas supply pipe that is not shown is connected to the gas chamber 144A and converges at a reactant gas supply source pipe 58. Each of gas flow rate regulators 56 is disposed between the reactant gas supply source pipe 58 and each of the gas chambers 144A, whereby a gas flow rate to each of the gas chambers 144A can be individually adjusted.

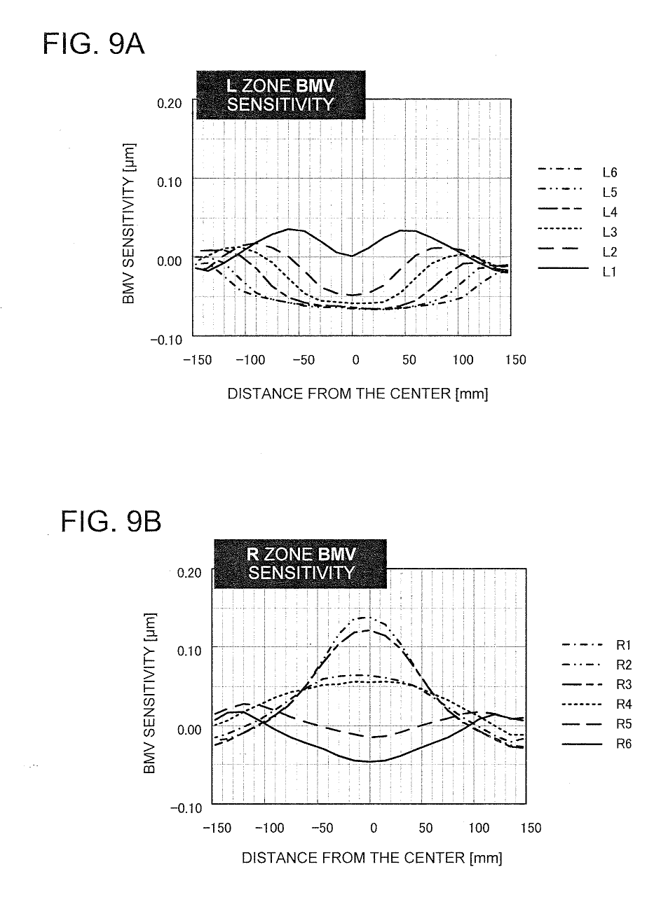

FIG. 9 is a view illustrating a film formation characteristic for a film formation reactive apparatus. In FIG. 9, a BMV (Bellows Metering Valve) sensitivity is used as an example of the film formation characteristics. FIG. 9A shows a BMV sensitivity of each flow path in an L zone (on a left side of the reference line: on the rotation downstream side), and FIG. 9B shows a BMV sensitivity of each flow path in an R zone. The BMV sensitivity indicates an amount of a change of a thickness of a film at each position of a wafer in the case in which a rotation film formation is carried out while only an aperture of one valve to be a target is changed to a large value (for instance 0.75) and a thickness of a film at each position of a wafer is a reference value in the case in which a rotation film formation is carried out while an aperture of all valves is a predetermined value (for instance 0.5). The film growth sensitivity in a rotation is obtained by dividing each value of the BMV sensitivity by an epitaxial growth time and a total gas flow rate. Consequently, the BMV sensitivity and the film growth sensitivity in a rotation show similar trends.

As shown in FIG. 9A and FIG. 9B, the BMV sensitivity of the flow paths R1 to R4 (in particular R2 and R3 among them) is higher in the range of 50 mm from the center of the wafer (a center part), and has a greater effect on the control of a thickness of a film at the center part. Moreover, the BMV sensitivity of the flow paths L1 to L4 (in particular L1 among them) is higher in the range of 50 mm to 100 mm from the center of the wafer (a middle part: an area that is closer to the almost intermediate position of a radius of the wafer), and has a greater effect on the control of a thickness of a film at the middle part. Moreover, the BMV sensitivity of the flow paths L3 to L6 (in particular L5 and L6 among them) is higher in the range of 100 mm to 150 mm from the center of the wafer (an edge part: a peripheral part), and has a greater effect on the control of a thickness of a film at the edge part. Since the flow paths L3 and L4 have the sensitivity to a certain degree for both of the middle part and the edge part, the flow paths L3 and L4 have a greater effect on the control of a thickness of a film to the both.

In the above described embodiment, a gas flow rate can be adjusted for each zone of the three zones: an R zone that includes an area that is corresponded to the flow paths R2 and R3 having a particularly strong sensitivity in the center part, an LR zone that includes an area that is corresponded to the flow paths L1 and L2 having a particularly strong sensitivity in the middle part, and an LL zone that includes an area that is corresponded to the flow paths L5 and L6 having a particularly strong sensitivity in the edge part. Consequently, a thickness of a film in the center part, the middle part, and the edge part of the wafer can be adjusted in an appropriate manner, whereby a thickness of a film for the entire of the wafer can be adjusted in an appropriate manner.

A method for dividing zones to adjust a gas flow rate is not limited to the above described embodiment, and a variety of methods can also be adopted. Modified examples in which methods for dividing zones to adjust a gas flow rate are modified will be described in the following.

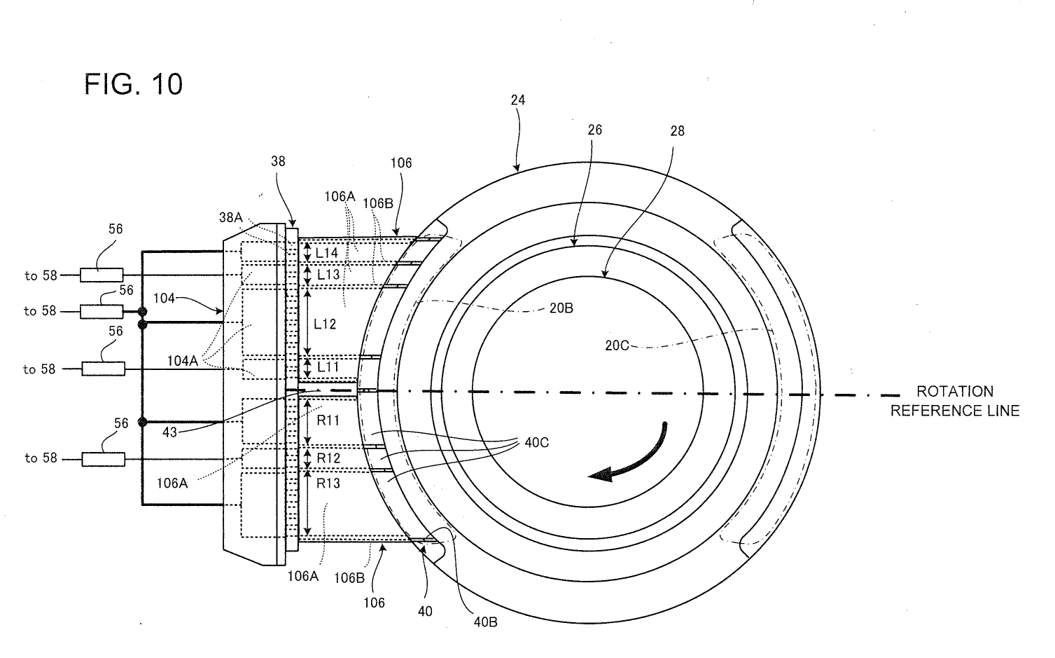

FIG. 10 is a view showing a configuration of a part for a gas flow supply of a film formation reactive apparatus according to a first modified example of the present invention.

The inserter 106 for the film formation reactive apparatus is provided with a flow path R11 of a range that is corresponded to the flow paths R1 and R2 of FIG. 8, a flow path R12 of a range that is corresponded to the flow path R3 having a strong sensitivity to the center part of the wafer 28, a flow path R13 of a range that is corresponded to the flow paths R4 to R6, a flow path L11 of a range that is corresponded to the flow path L1 having a strong sensitivity to the middle part of the wafer 28, a flow path L12 of a range that is corresponded to the flow paths L2 to L4, a flow path L13 of a range that is corresponded to the flow path L5 having a strong sensitivity to the edge part of the wafer 28, and a flow path L14 of a range that is corresponded to the flow path L6. It is preferable that a width of the flow paths L11, L13, and R12 is in the range of 10 to 30 mm, the flow path R12 is in the range of 0 to 120 mm on the right side of the reference line, the flow path L11 is in the range of 0 to 60 mm on the left side of the reference line, and the flow path L13 is in the range of 90 to 180 mm on the left side of the reference line. The flow paths L11, L13, and R12 are corresponded to each of the partial control zones, and the flow paths L12, L14, R11, and R13 are corresponded to one partial control zone.

The inlet flange 104 is provided with a gas chamber 104A that is corresponded to and communicates with each of the flow paths L11 to L14 and the flow paths R11 to R13. The gas chambers 104A that communicate with the flow path L11, the flow path L13, and the flow path R12 are connected to the reactant gas supply source pipe 58 via the different gas flow rate regulators 56. Consequently, a gas flow rate can be individually adjusted for the flow path L11 having a strong sensitivity to the middle part of the wafer 28, the flow path L13 having a strong sensitivity to the edge part of the wafer 28, and the flow path R12 having a strong sensitivity to the center part of the wafer 28. Therefore, a thickness of a film in the center part, the middle part, and the edge part of the wafer can be adjusted in an appropriate manner. Moreover, the gas chambers 104A that communicate with the flow path R11, the flow path R13, the flow path L12, and the flow path L14 are connected to the reactant gas supply source pipe 58 via one gas flow rate regulator 56.

For the present film formation reactive apparatus, by the processing that is equal to the above described gas flow rate adjustment processing shown in FIG. 5, a gas flow rate is adjusted for the flow path L11 having a strong sensitivity to the middle part of the wafer 28, the flow path L13 having a strong sensitivity to the edge part of the wafer 28, the flow path R12 having a strong sensitivity to the center part of the wafer 28, and other flow paths (R11, R13, L12, and L14). Therefore, a thickness of a film of the wafer can be controlled in an appropriate manner.

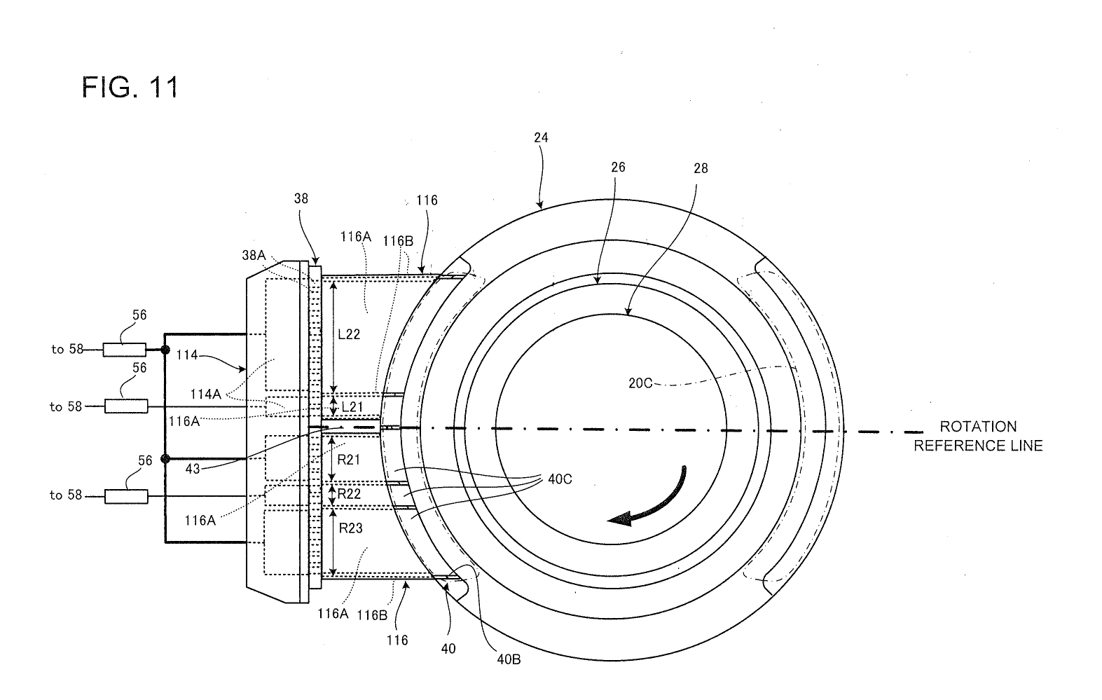

FIG. 11 is a view showing a configuration of a part for a gas flow supply of a film formation reactive apparatus according to a second modified example of the present invention.

The inserter 116 for the film formation reactive apparatus is provided with a flow path R21 of a range that is corresponded to the flow paths R1 and R2 of FIG. 8, a flow path R22 of a range that is corresponded to the flow path R3 having a strong sensitivity to the center part of the wafer 28, a flow path R23 of a range that is corresponded to the flow paths R4 to R6, a flow path L21 of a range that is corresponded to the flow path L1 having a strong sensitivity to the middle part of the wafer 28, and a flow path L22 of a range that is corresponded to the flow paths L2 to L6. It is preferable that a width of the flow paths L21 and R22 is in the range of 10 to 30 mm, the flow path R22 is in the range of 0 to 120 mm on the right side of the reference line, and the flow path L21 is in the range of 0 to 60 mm on the left side of the reference line.

The inlet flange 114 is provided with a gas chamber 114A that is corresponded to and communicates with each of the flow paths L21 to L22 and the flow paths R21 to R23. The gas chambers 114A that communicate with the flow path L21 and the flow path R22 are connected to the reactant gas supply source pipe 58 via the different gas flow rate regulators 56. Consequently, a gas flow rate can be individually adjusted for the flow path L21 that has a strong sensitivity to the middle part of the wafer 28 and the flow path R22 having a strong sensitivity to the center part of the wafer 28. Therefore, a thickness of a film in the center part and the middle part of the wafer can be adjusted in an appropriate manner. Moreover, the gas chambers 114A that communicate with the flow path R21, the flow path R23, and the flow path L22 are connected to the reactant gas supply source pipe 58 via one gas flow rate regulator 56.

For the present film formation reactive apparatus, prior to carrying out the above described gas flow rate adjustment processing shown in FIG. 5, a Si gas concentration is adjusted by the gas flow rate regulator 53 in such a manner that a thickness of a film in the edge part of the wafer is an almost desired thickness of a film. More specifically, a rotating film formation is carried out for a wafer and a thickness of a film of the wafer is measured in the state in which an aperture of the gas flow rate regulator 56 is specified to be a predetermined value. In addition, by repeating the processing for adjusting the Si gas concentration by the gas flow rate regulator 53 based on the results of the measurement, the gas flow rate regulator 53 is adjusted in such a manner that a thickness of a film in the edge part of the wafer is close to a desired thickness of a film. By these steps, for the edge part of the wafer, a desired thickness of a film can be obtained by the adjustment.

After that, by carrying out the above described gas flow rate adjustment processing shown in FIG. 5, the gas flow rate regulator 56 is adjusted. By this step, for the middle part and the center part of the wafer, a desired thickness of a film can also be obtained by the adjustment. Therefore, a thickness of a film of the wafer can be controlled in an appropriate manner.

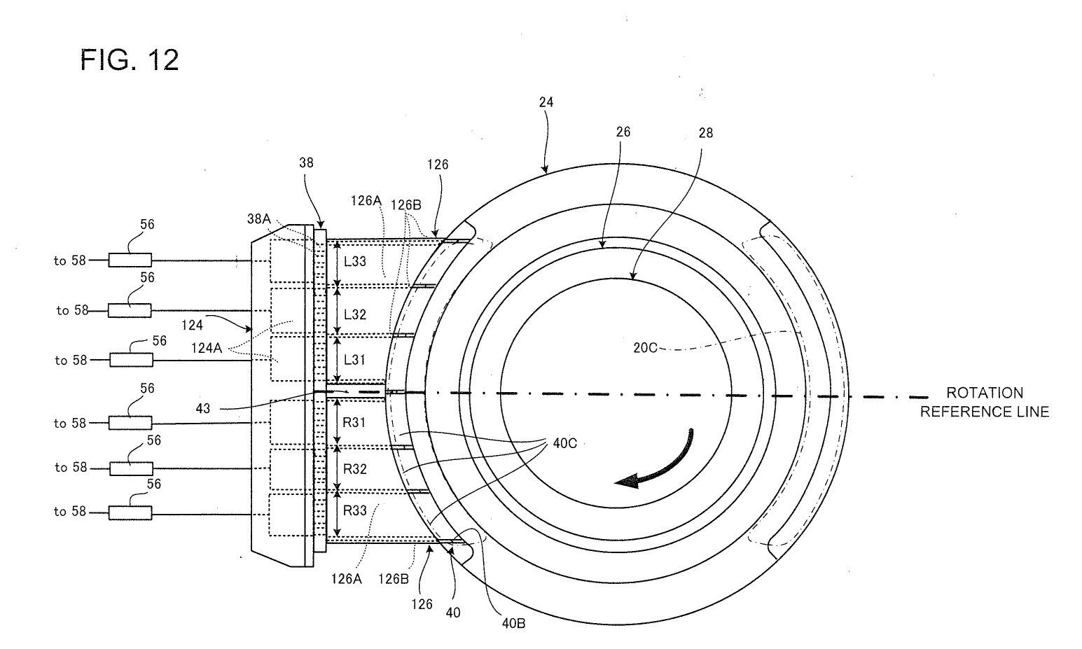

FIG. 12 is a view showing a configuration of a part for a gas flow supply of a film formation reactive apparatus according to a third modified example of the present invention.

The inserter 126 for the film formation reactive apparatus is provided with a flow path R31 of a range that is corresponded to the flow paths R1 and R2 of FIG. 8, a flow path R32 of a range that is corresponded to the flow paths R3 and R4, a flow path R33 of a range that is corresponded to the flow paths R5 and R6, a flow path L31 of a range that is corresponded to the flow paths L1 and L2, a flow path L32 of a range that is corresponded to the flow paths L3 and L4, and a flow path L33 of a range that is corresponded to the flow paths L5 and L6.

The inlet flange 124 is provided with a gas chamber 124A that is corresponded to and communicates with each of the flow paths L31 to L33 and the flow paths R31 to R33. The gas chambers 124A that communicate with each of the flow paths L31 to L33 and the flow paths R31 to R33 are connected to the reactant gas supply source pipe 58 via the different gas flow rate regulators 56. Consequently, a gas flow rate can be individually adjusted for each of the flow paths L31 to L33 and the flow paths R31 to R33. Therefore, a thickness of a film in each part of the wafer can be adjusted in an appropriate manner. By this configuration, a thickness of a film of the wafer can be controlled in an appropriate manner by the relatively less gas flow rate regulators 56.

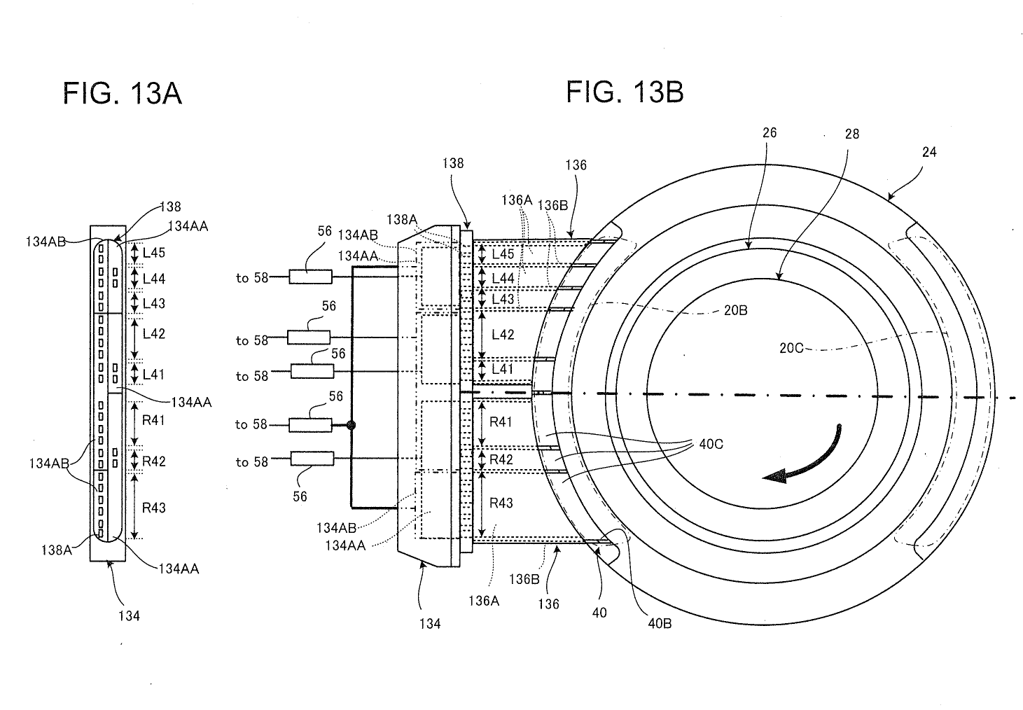

FIG. 13 is a view showing a configuration of a part for a gas flow supply of a film formation reactive apparatus according to a fourth modified example of the present invention. FIG. 13A is a cross sectional view showing the inlet flange 134, and FIG. 13B is a top view showing a configuration of a part.

The inserter 136 for the film formation reactive apparatus is provided with a flow path R41 of a range that is corresponded to the flow paths R1 and R2 of FIG. 8, a flow path R42 of a range that is corresponded to the flow path R3, a flow path R43 of a range that is corresponded to the flow paths R4 to R6, a flow path L41 of a range that is corresponded to the flow path L1, a flow path L42 of a range that is corresponded to the flow paths L2 and L3, a flow path L43 of a range that is corresponded to the flow path L4, a flow path L44 of a range that is corresponded to the flow path L5, and a flow path L45 of a range that is corresponded to the flow path L6. It is preferable that a width of the flow paths L41, L44, and R42 is in the range of 10 to 30 mm, the flow path R42 is in the range of 0 to 120 mm on the right side of the reference line, the flow path L41 is in the range of 0 to 60 mm on the left side of the reference line, and the flow path L44 is in the range of 90 to 180 mm on the left side of the reference line. For the flow paths R42, L41, and L44, gases of different flow rates can flow on the upper side of the flow path (the upper side in a perpendicular direction of a plane of a paper) and on the lower side of the flow path (the lower side in a perpendicular direction of a plane of a paper).

As shown in FIG. 13A, a plurality of the flow rectifying holes 138A in a long, narrow slit shape in the widthwise direction are formed on the lower side of the baffle 138 (on the left side of FIG. 13A) in such a manner that each of the flow rectifying holes 138A is corresponded to each flow path. Moreover, the flow rectifying holes 138A are formed on the upper side of the, baffle 138 at the positions that are corresponded to the flow paths L41, L44, and R42.

The inlet flange 134 is provided with a gas chamber 134A of two stages in a vertical direction. In the lower stage, there are formed a gas chamber 134AB that communicates with via the flow rectifying hole 138A on the lower side of the flow paths L41 and L42 and the flow paths R41 and R42, a gas chamber 134AB that communicates with via the flow rectifying hole 138A on the lower side of the flow paths L43, L44, and L45, and a gas chamber 134AB that communicates with via the flow rectifying hole 138A on the lower side of the flow path R43. In the upper stage, there are formed a gas chamber 134AA that communicates with via the flow rectifying hole 138A on the upper side of the flow path L44, a gas chamber 134AA that communicates with via the flow rectifying hole 138A on the upper side of the flow path L41, and a gas chamber 134AA that communicates with via the flow rectifying hole 138A on the upper side of the flow path R42.

The gas chambers 134AB that communicate with each of the flow paths L41 and L42 and the flow paths R41 and R42 that are located at an almost central position of the gas inlet port are connected to the reactant gas supply source pipe 58 via one gas flow rate regulator 56. Moreover, the gas chambers 134AB that communicate with each of the flow paths L43 to L45 that are located outside the gas inlet port and the gas chambers 134AB that communicate with the flow path R43 are connected to the reactant gas supply source pipe 58 via the same gas flow rate regulator 56. By adjusting the two gas flow rate regulators 56, a gas can be made flow to the entire in the widthwise direction. The gas chambers 134AA that communicate with each of the flow paths L41 and L44 and the flow path R42 are connected to the reactant gas supply source pipe 58 via the different gas flow rate regulators 56. Consequently, two gas supply system paths exist for the flow paths L41 and L44 and the flow path R42.

For the present film formation reactive apparatus, prior to carrying out the above described gas flow rate adjustment processing shown in FIG. 5, a gas flow rate of the gas chamber 134AB that communicates with each of the flow paths L43, L44, and L45 on the lower side is adjusted by the gas flow rate regulator 56, and a gas flow rate of the gas chamber 134AB that communicates with each of the flow paths R41 and R42 and the flow paths L41 and L42 on the lower side is adjusted by the gas flow rate regulator 56. Consequently, a rotating film formation is carried out for a wafer and a thickness of a film of the wafer can be close to a desired thickness of a film to a certain degree.

After that, by carrying out the above described gas flow rate adjustment processing shown in FIG. 5, a gas flow rate is controlled for a region on the upper side of the flow paths L41, L44, and R42 as a target of an adjustment. More specifically, an aperture of the gas flow rate regulator 56 that is connected to each of the gas chamber 134AA that communicates with the flow path L41 on the upper side, the gas chamber 134AA that communicates with the flow path L44 on the upper side, and the gas chamber 134AA that communicates with the flow path R42 on the upper side is adjusted by the gas flow rate adjustment processing. By this step, for the middle part, the center part, and the edge part of the wafer 28, an appropriate thickness of a film can be obtained.

While the preferred embodiments in accordance with the present invention have been described above, the present invention is not limited to the above described embodiments, and various changes, modifications, and functional additions can be thus made without departing from the scope of the present invention.

For instance, all zones (all partial control zones) are targets of an adjustment of a gas flow rate in the above embodiments. However, at least one zone can also be removed from the targets of an adjustment, that is, a gas flow rate can be fixed in advance, or a gas flow rate can be adjusted depending on the other zones, and a gas flow rate of the other zones can be adjusted. In this case, for the equation of the film growth rate deviation ΔGR(x) that has been described above, a term related to a zone in which a gas flow rate is fixed can be omitted, and a term related to a zone in which a gas flow rate can be adjusted depending on the other zones is expressed based on a flow rate adjustment value of the other zones that has an influence to the present zone. For instance, in the above embodiments, it is not necessary to dispose the gas flow rate regulator 56 that can individually adjust a gas flow rate of the LL zone. In this case, since a gas flow rate of the LL zone is determined depending on an aperture of the gas flow rate regulator 56 of the R zone and the LR zone, a flow rate adjustment value of a term related to the LL zone in the above equation can be expressed by a flow rate adjustment value of the LL zone and the LR zone. In the case in which a gas flow rate of the LL zone cannot be individually adjusted, a Si gas concentration is adjusted in advance in such a manner that a thickness of a film in the edge part of a wafer can be a desired thickness, and a gas flow rate adjustment processing as shown in FIG. 5 can then be carried out.

Moreover, although the LR zone is up to 90 mm on the left side from the reference line in the above embodiments, the present invention is not limited to the configuration. A width of the LR zone can be at least 10 mm, and the LR zone can be located in the range up to 90 mm on the left side from the reference line.

What is claimed is:

1. A film formation reactive apparatus for forming a film on a substrate, comprising:
a reaction chamber configuration part that configures a reaction chamber in which a substrate is placed;
a gas inlet port part that configures gas inlet port that extends in a predetermined range in a widthwise direction along a periphery of the substrate placed inside the reaction chamber for introducing a reactant gas flow into the reaction chamber;
a plurality of partial control zones that are configured on an upstream side of the gas inlet port and that can control a gas flow rate; and
a gas flow rate control part that controls a gas flow rate of the plurality of partial control zones,
the gas flow rate control part comprising:
a first unit that obtains a deviation between a film growth rate and a predetermined target film growth rate at a variety of locations on the substrate based on the data of a thickness of a film that has been formed on the substrate by a rotating film formation carried out while rotating the substrate; and
a second unit that controls the respective gas flow rates of the partial control zones to be adjusted by using the rotation film growth sensitivity data that defines a sensitivity to a change in a film growth rate distribution during the rotating film formation on the substrate in such a manner that a change in the respective gas flow rates of the plurality of partial control zones causes the deviation at a variety of the locations to be reduced.

2. The film formation reactive apparatus according to claim 1, wherein different partial control zones are configured on the rotation upstream side and on the rotation downstream side of a reference line that is parallel to a direction of a gas flow caused by the gas inlet port and that passes through a rotation central axis of the substrate.

3. The film formation reactive apparatus according to claim 2, wherein at least two partial control zones of the rotation upstream side and the rotation downstream side are configured on the rotation downstream side of the reference line.

4. The film formation reactive apparatus according to claim 3, wherein one partial control zone is configured on the rotation upstream side of the reference line and two partial control zones of the rotation upstream side and the rotation downstream side are configured on the rotation downstream side of the reference line.

5. The film formation reactive apparatus according to claim 1, wherein the plurality of partial control zones are provided with a first partial control zone that has a high tendency to contribute to a film formation close to the center of the substrate and a second partial control zone that has a high tendency to contribute to a film formation almost close to the intermediate position of a radius of the substrate.

6. The film formation reactive apparatus according to claim 2, wherein the plurality of partial control zones are provided with a first partial control zone that has a high tendency to contribute to a film formation close to the center of the substrate and a second partial control zone that has a high tendency to contribute to a film formation almost close to the intermediate position of a radius of the substrate.

7. The film formation reactive apparatus according to claim 3, wherein the plurality of partial control zones are provided with a first partial control zone that has a high tendency to contribute to a film formation close to the center of the substrate and a second partial control zone that has a high tendency to contribute to a film formation almost close to the intermediate position of a radius of the substrate.

8. The film formation reactive apparatus according to claim 4, wherein the plurality of partial control zones are provided with a first partial control zone that has a high tendency to contribute to a film formation close to the center of the substrate and a second partial control zone that has a high tendency to contribute to a film formation almost close to the intermediate position of a radius of the substrate.

9. The film formation reactive apparatus according to claim 5, wherein the plurality of partial control zones are composed of three partial control zones: a first partial control zone that has a high tendency to contribute to a film formation close to the center of the substrate, a second partial control zone that has a high tendency to contribute to a film formation almost close to the intermediate position of a radius of the substrate, and the other partial control zone.

10. The film formation reactive apparatus according to claim 6, wherein the plurality of partial control zones are composed of three partial control zones: a first partial control zone that has a high tendency to contribute to a film formation close to the center of the substrate, a second partial control zone that has a high tendency to contribute to a film formation almost close to the intermediate position of a radius of the substrate, and the other partial control zone.

11. The film formation reactive apparatus according to claim 7, wherein the plurality of partial control zones are composed of three partial control zones: a first partial control zone that has a high tendency to contribute to a film formation close to the center of the substrate, a second partial control zone that has a high tendency to contribute to a film formation almost close to the intermediate position of a radius of the substrate, and the other partial control zone.

12. The film formation reactive apparatus according to claim 8, wherein the plurality of partial control zones are composed of three partial control zones: a first partial control zone that has a high tendency to contribute to a film formation close to the center of the substrate, a second partial control zone that has a high tendency to contribute to a film formation almost close to the intermediate position of a radius of the substrate, and the other partial control zone.

13. The film formation reactive apparatus according to claim 5, wherein the plurality of partial control zones are provided with a third partial control zone that has a high tendency to contribute to a film formation close to the outer circumference of the substrate.

14. The film formation reactive apparatus according to claim 6, wherein the plurality of partial control zones are provided with a third partial control zone that has a high tendency to contribute to a film formation close to the outer circumference of the substrate.

15. The film formation reactive apparatus according to claim 7, wherein the plurality of partial control zones are provided with a third partial control zone that has a high tendency to contribute to a film formation close to the outer circumference of the substrate.

16. The film formation reactive apparatus according to claim 8, wherein the plurality of partial control zones are provided with a third partial control zone that has a high tendency to contribute to a film formation close to the outer circumference of the substrate.

17. The film formation reactive apparatus according to claim 13, wherein the plurality of partial control zones are composed of four partial control zones: the first partial control zone, the second partial control zone, the third partial control zone, and the other partial control zone.

18. The film formation reactive apparatus according to claim 14, wherein the plurality of partial control zones are composed of four partial control zones: the first partial control zone, the second partial control zone, the third partial control zone, and the other partial control zone.

19. The film formation reactive apparatus according to claim 1, wherein a gas adjustment mechanism that adjusts a gas flow rate in the partial control zone is disposed for every partial control zone.

20. A method for producing a film-formed substrate while rotating the substrate, comprising:
a step of making a reactant gas to flow to the substrate for a film formation;
a step of producing a film-formed substrate by adjusting a gas flow rate for the reactant gas flow to be a predetermined rate for each of a plurality of partial control zones to carry out a film formation while rotating the substrate;
a step of obtaining a deviation between a film growth rate and a predetermined target film growth rate at a variety of locations on the substrate based on the data of a thickness of a film that has been formed on the substrate by the rotating film formation carried out while rotating the substrate;
a step of determining a gas flow rate adjusted for the respective partial control zones to be adjusted by using the rotation film growth sensitivity data that defines a sensitivity to a change in a film growth rate distribution during the rotating film formation on the substrate in such a manner that a change in the respective gas flow rates of the plurality of partial control zones causes the deviation at a variety of the locations to be reduced; and
a step of producing the film-formed substrate by adjusting the respective gas flow rates of the plurality of partial control zones to be the determined gas flow rate to carry out a film formation while rotating a new substrate.
